(19) United States
(12) Patent Application Publication
(10) Pub. No.: US 2003/0049920 A1
(43) Pub. Date: Mar. 13, 2003

(54) Manufacturing method of semiconductor device

(76) Inventor: Shoji Koyama, Tokyo (JP)

Correspondence Address: KATTEN MUCHIN ZAVIS ROSENMAN, 575 MADISON AVENUE, NEW YORK, NY, 10022-2585, US

(21) Appl. No.: 10/237,770

(22) Filed: Sep. 9, 2002

(30) Foreign Application Priority Data
Sep. 11, 2001 (JP) 2001-275079

(51) Int. Cl. H01L 21/44; H01L 21/4763

(52) U.S. Cl. 438/597; 438/637

(57) ABSTRACT

The present invention relates to a method of manufacturing a semiconductor device; which comprises the steps of: forming an interlayer insulating film on a semiconductor substrate having a gate electrode, a dopant diffusion layer and a silicide layer which is set on said dopant diffusion layer; forming an opening in said interlayer insulating film which is laid on said dopant diffusion layer in such a way that said silicide layer may not be exposed; forming, in a region inclusive of internal lateral faces of said opening, an insulating film for sidewall at or above 700° C. by the CVD; and performing an etch back and thereby forming, on the internal lateral face of said opening, a sidewall made of said insulating film for sidewall.

### BACKGROUND OF THE INVENTION

1. Field of the Invention

The present invention relates to a method of manufacturing a semiconductor device and more particularly to a method of forming a minute contact structure.

2. Description of the Related Art

In recent years, accompanying the advance in further miniaturization of the semiconductor device and the development of more densely spaced arrangement, there have been growing demands for the miniaturization of the contact which electrically connects the dopant diffusion layer of the semiconductor substrate with the conductive substance layer such as the interconnection.

The formation of a contact has been, hitherto, carried out by forming, in the interlayer insulating film lying on the semiconductor substrate, a contact hole to reach the dopant diffusion layer and then filling up the inside of the contact hole with the conductive material. However, for the miniaturization of the contact, the contact hole must be also miniaturized, and its formation by patterning has become considerably difficult. Accordingly, there has become in use a method in which a contact hole is formed deliberately on the large side and thereafter, on its internal lateral faces, sidewalls are formed of the insulating material so as to make the aperture of the contact hole small. Such a forming method of a contact is disclosed, for example, in Japanese Patent Application Laid-open No. 77170/1989.

The conventional forming method of a contact is described in detail below.

Firstly, after a gate insulating film 102 is formed by the thermal oxidation method or the like on a semiconductor substrate 101 in which an element isolation region (not shown in the drawings) is set, a doped polycrystalline silicon layer is formed over the entire element formation surface of the substrate by the CVD (Chemical Vapor Deposition), and then, by patterning this layer, gate electrodes 103 are formed. Next, using the gate electrodes as a mask, the ion implantation is applied thereto to form dopant diffusion layers 104. After that, an interlayer insulating film 105 is formed thereon (FIG. 5(a)).

Next, as shown in FIG. 5(b), a prescribed mask for etching (not shown in the drawings) is formed by photolithography, and, using this mask, anisotropic etching is carried out, whereby a contact hole 106 to reach the dopant diffusion layer 104 is formed.

Next, as shown in FIG. 5(c), a silicon oxide film 107 for sidewall is formed over the entire surface by the CVD.

Next, as shown in FIG. 5 (d), an etch back is made by anisotropic etching such as the RIE (Reactive Ion Etching) so as to expose the dopant diffusion layer 104 at the bottom of the contact hole 106. As a result, sidewalls 108 are formed on the lateral faces inside of the contact hole.

After that, by the sputtering or such, a conductive substance layer is formed over the entire surface so as to fill up the inside of the contact hole 106 and, then, by patterning this conductive substance layer, an interconnection 109 as well as a contact 110 which connects this interconnection with the dopant diffusion layer 104 are formed (FIG. 5(e)).

Meanwhile, it is considered that recent miniaturization of the semiconductor device calls for the reduction of sheet resistance and contact resistance for the source/drain regions, and, consequently, necessitates setting of silicide layers on the source/drain regions.

Now, in the afore-mentioned conventional method, the demands for still further miniaturization of the contact give rise to the necessity to form even the contact hole prior to the sidewall formation, minutely.

However, when the contact hole is miniaturized, in other words, when the aperture of the contact hole is made small and the aspect ratio thereof is made large, this may bring about another problem that the formation of a uniform insulating film for sidewall on the sidewalls inside of the contact hole becomes difficult. Such a problem may result in a poor filling of the inside of the contact hole with the conductive material, a faulty contact with the dopant diffusion layer in the bottom section of the contact hole or a short circuit between the conductive material inside of the contact hole and the gate electrode, and, therefore, a satisfactory contact may become difficult to be formed.

In order to avoid problems of this sort and attain high uniformity in film thickness of the insulating film for sidewall, it is required to form the insulating film for sidewall at a relatively high temperature of 700° C. to 800° C. by the CVD. However, when a silicide layer is set on top of the dopant diffusion layer, the deposition of the insulating film at such a high temperature causes, due to its high temperature, abnormal oxidation of the portion of the silicide layer exposed at the bottom of the contact hole, and the silicide layer may lose its original function thereat. Further, the apparatus for film deposition in use may be contaminated by the metal which comes from the silicide layers, and, in turn, the semiconductor devices being worked in that apparatus for film deposition may receive metal contamination, which shortens the lifetime of carriers in the semiconductor devices.

### SUMMARY OF THE INVENTION

In light of the above problems, an object of the present invention is to provide a method of manufacturing a semiconductor device, capable to form a minute contact well, without making the silicide layer which is set on the dopant diffusion layer undergo abnormal oxidation or contaminating the apparatus for film deposition.

The present invention relates to a method of manufacturing a semiconductor device; which comprises the steps of:

forming an interlayer insulating film on a semiconductor substrate having a gate electrode, a dopant diffusion layer and a silicide layer which is set on said dopant diffusion layer;

forming an opening in said interlayer insulating film which is laid on said dopant diffusion layer in such a way that said silicide layer may not be exposed;

forming, in a region inclusive of internal lateral faces of said opening, an insulating film for sidewall at or above 700° C. by the CVD;

performing an etch back and thereby forming, on the internal lateral face of said opening, a sidewall made of said insulating film for sidewall and, at the same time, removing said interlayer insulating film lying under said opening, whereby a contact hole to expose said silicide layer is formed; and

filling up said contact hole with a conductive material.

Further, the present invention relates to a method of manufacturing a semiconductor device; which comprises the steps of:

forming a first insulating film on a semiconductor substrate having a gate electrode, a dopant diffusion layer and a silicide layer which is set on said dopant diffusion layer, and subsequently forming an interlayer insulating film thereon;

forming, in said interlayer insulating film which is laid on said dopant diffusion layer, an opening to reach said first insulating film, using said first insulating film as an etching stopper;

forming, in a region inclusive of internal lateral faces of said opening, a second insulating film at or above 700° C. by the CVD;

performing an etch back and thereby removing said second insulating film lying under said opening to form, on the internal lateral face of said opening, a sidewall made of said second insulating film, and, subsequently, removing said first insulating film lying under said opening, whereby a contact hole to expose said silicide layer is formed; and

filling up said contact hole with a conductive material.

In the present invention, because no silicide layers are exposed while forming the insulating film for sidewall to provide sidewalls on the internal lateral faces of the contact hole, even if the film is grown at a high temperature of not less than 700° C., abnormal oxidation of the silicide layers and metal contamination of the apparatus for film deposition can be well prevented from taking place. In consequence, a minute contact can be formed well, without shortening the lifetime of carriers in the semiconductor device.

That is, the present invention can provide a method of manufacturing a semiconductor device, capable to form a minute contact well, without making the silicide layer which is set on the dopant diffusion layer undergo abnormal oxidation or contaminating the apparatus for film deposition.

### BRIEF DESCRIPTION OF THE DRAWINGS

FIG. 1 is a series of schematic cross-sectional views illustrating the steps of an embodiment of a manufacturing method of a semiconductor device according to the present invention.

FIG. 2 is a series of schematic cross-sectional views illustrating the steps of another embodiment of a manufacturing method of a semiconductor device according to the present invention.

FIG. 3 is a series of schematic cross-sectional views illustrating the steps of another embodiment of a manufacturing method of a semiconductor device according to the present invention.

FIG. 4 is a series of schematic cross-sectional views illustrating the steps of another embodiment of a manufacturing method of a semiconductor device according to the present invention.

FIG. 5 is a series of schematic cross-sectional views illustrating the steps of a conventional manufacturing method of a semiconductor device.

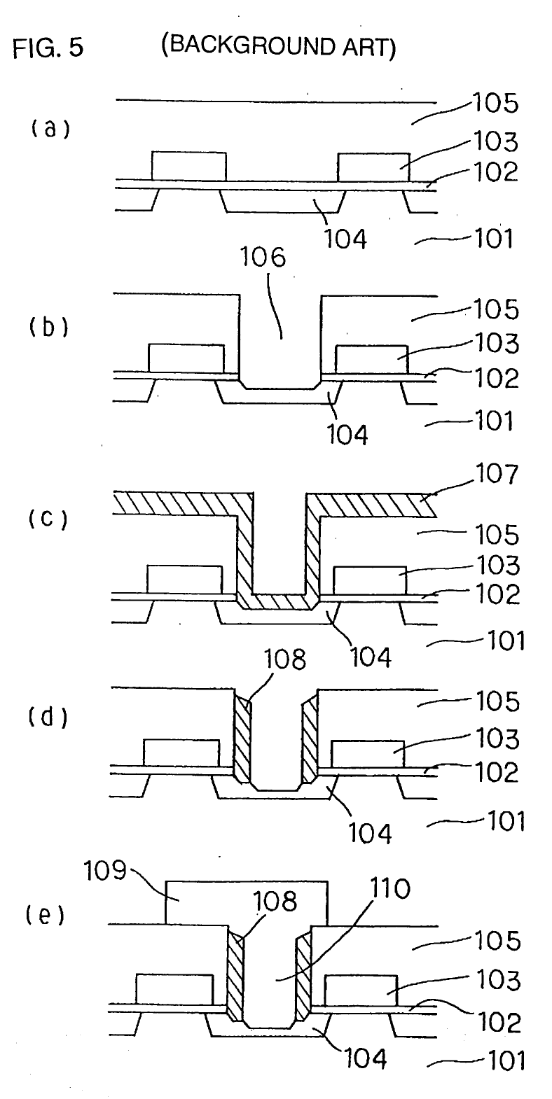

### DETAILED DESCRIPTION OF THE INVENTION

The preferred embodiments of the present invention are described in detail below.

### First Embodiment

Firstly, after a gate insulating film 2 with a thickness of 2 nm to 20 nm or so is formed by the thermal oxidation method or the like on a semiconductor substrate 1 in which an element isolation region (not shown in the drawings) is set, a doped polycrystalline silicon layer with a thickness of 100 nm to 200 nm or so is formed over the entire element formation surface (referred to as “the entire surface” hereinafter) of the substrate by the CVD (Chemical Vapor Deposition), and then, by patterning this layer, gate electrodes 3 are formed. Next, using the gate electrodes 3 as a mask, an ion implantation is applied thereto under the condition that an accelerating energy is 5 keV to 60 keV and a dose is 5×10¹⁴/cm² to 7×10¹⁵/cm² or so, and, thereby, dopant diffusion layers 4 are formed. In this instance, boron (B) or BF₂ may be employed for the p-type dopants, and phosphorus (P) or arsenic (As), for the n-type dopants. Hereat, it is also possible to form a channeling stop film from a silicon oxide film or the like over the entire surface and, then, apply this ion implantation thereto through this film. The dopant diffusion layers 4 formed in this way are afterward subjected to a dopant activation treatment by means of a heat treatment conducted at 700° C. to 1000° C. or so, whereby source/drain regions of the MOSFET (Metal-Oxide Semiconductor Field Effect Transistor) are formed.

Next, over the dopant diffusion layers silicide layers 21 are formed, for example, in the following way. First, over a region inclusive of exposed dopant diffusion layers, a metal film of Co, Ti or such is formed by the sputtering method. A heat treatment at 600° C. to 800° C. or so is then applied thereto to bring about a silicide formation reaction between the metal film and silicon of the dopant diffusion layers and between the metal film and silicon of the gate electrodes. Portions of the unreacted metal film which are left on the insulating region such as the element isolation region and the like are removed by etching. As a result, silicide layers 21 are formed, in the manner of self-align, on the dopant diffusion layers 4 as well as on the gate electrodes 3.

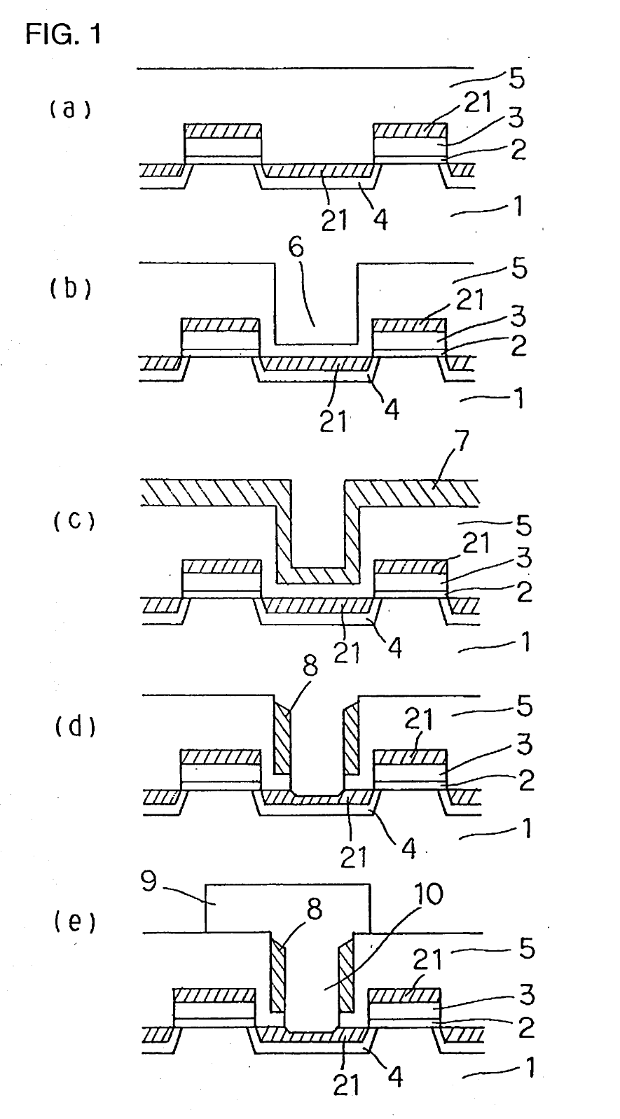

After that, an interlayer insulating film 5 with a thickness of 300 nm to 1000 nm or so is formed (FIG. 1(a)). As an interlayer insulating film, a silicon oxide film, a BPSG (Boron Phosphorous Silicate Glass) film, a NSG (Non-doped Silicate Glass) film or such may be formed by the CVD.

In the case that the interlayer insulating film is formed on the surface where silicide layers are exposed, the deposition temperature for the film is preferably set at or below 600° C. When the deposition temperature is too high, the apparatus for film deposition may be contaminated by the metal which comes from the silicide layers, and, in turn, the semiconductor devices being worked in that apparatus for film deposition may receive metal contamination, which shortens the lifetime of carriers in the semiconductor devices. Further, if, in an oxidizing atmosphere where oxygen (O₂), ozone (O₃) or such is present, the deposition temperature is set excessively high, abnormal oxidation of the silicide layers may be brought about and the original function of the silicide layers may be lost. Viewed from the points of achieving suppression of such metal contamination and abnormal oxidation more thoroughly, the deposition temperature is preferably set at or below 500° C. For instance, the application of the atmospheric pressure CVD with the deposition temperature being set at 400° C. to 500° C. can form a prescribed interlayer insulating film well, while preventing the afore-mentioned metal contamination and abnormal oxidation from occurring.

Next, as shown in FIG. 1 (b), an opening 6 is formed in the interlayer insulating film 5 by means of lithography and anisotropic etching. Thereat, etching is terminated before the silicide layers overlying the dopant diffusion layer 4 are exposed.

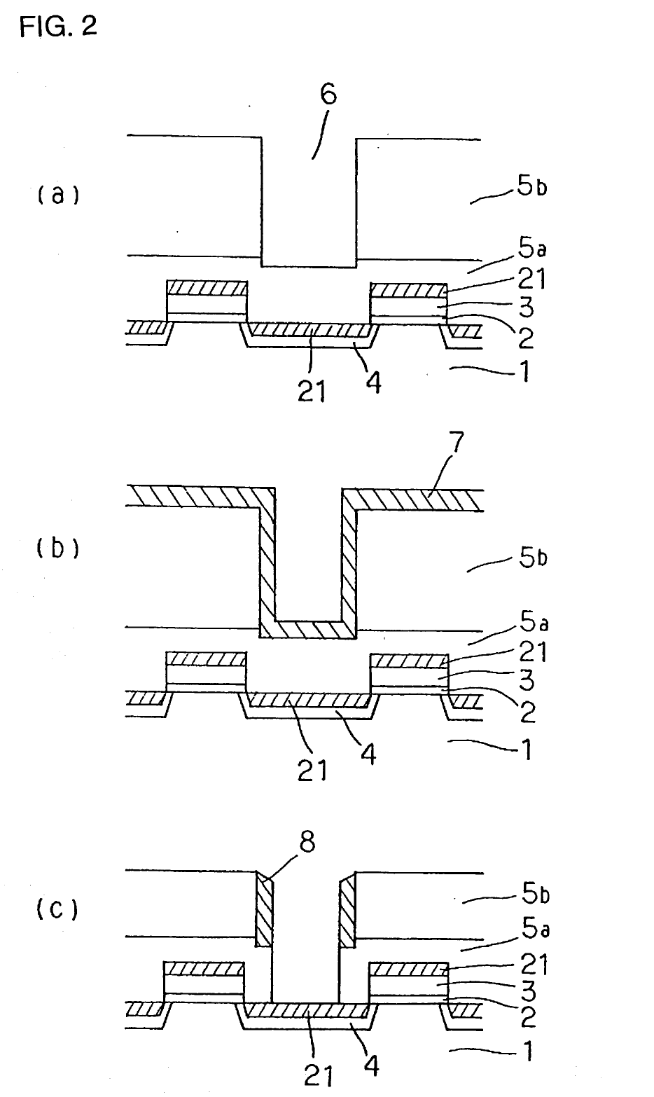

The etching end point can be determined, for instance, from the etching rate and the thickness of the interlayer insulating film. Or, if the interlayer insulating film is formed to have a layered structure with two or more layers of different materials, it is possible to monitor the substances produced in etching and determine the etching end point from the change of the etching products or the change in concentration of an etching product. For example, when an opening 6 is formed in an interlayer insulating film wherein a NSG film 5a is set as a lower layer and a BPSG film 5b, as an upper layer, as shown in FIG. 2(a), a point of time when the detection of boron (B) compounds and phosphorus (P) compounds just ends or another point of time when a certain prescribed time period passes after that point of time can be selected as the etching end point.

Next, as shown in FIG. 1 (c) or FIG. 2(b), an insulating film 7 for sidewall is formed from a silicon oxide film or such over the entire surface by the CVD. The formation of the insulating film for sidewall is required to be made at or above 700° C. and preferably in a range of 700° C. to 800° C. so that uniform deposition on the internal lateral faces of the minute opening may be obtained. Further, the deposition of the film by the low pressure CVD is preferable.

Next, an etch back is performed over the entire surface by anisotropic etching such as the RIE, and thereby a sidewall 8 is formed on the internal lateral face of the opening and, at the same time, the silicide layer 21 overlying the dopant diffusion layer is exposed (FIG. 1(d), FIG. 2(c)).

After that, as shown in FIG. 1(e), by the sputtering method or such, a conductive substance layer is formed over the entire surface so as to fill up the inside of the opening and, then, by patterning this conductive substance layer by means of lithography and anisotropic etching, an interconnection 9 as well as a contact 10 which connects this interconnection 9 with the dopant diffusion layer 4 are formed. It is also possible that after the inside of the opening is filled up with a conductive material, the portion of the conductive material lying outside of the opening is removed, by the CMP (Chemical Mechanical Polishing) or etching, to form a contact first, and, then, a conductive substance layer which is to be used for the interconnection formation is grown and, by patterning this conductive substance layer, an interconnection is formed.

Hereat, the position of the etching end point shown in FIG. 1(b) or FIG. 2(a), that is, the position of the bottom face of the opening 6 is preferably set as near as possible to the top face of the silicide layer 21 overlying the dopant diffusion layer 4, within the limits that the silicide layer overlying the dopant diffusion layer may not be exposed, the etching accuracy being taken into consideration. In this way, at the time of the etch back for formation of the sidewalls 8 shown in FIG. 1(d) or FIG. 2(c), the amount of the decrease in film thickness of the interlayer insulating film 5 can be lessened. Further, when the margin between the contact and the gate electrode is small, it is preferable to set the position of the etching end point higher than the top face of the silicide layer overlying the gate electrode. Even if the opening in formation overlaps the position of the gate electrode, resulting from the alignment shift or the like, this arrangement does not allow the silicide layer overlying the gate electrode to be exposed so that abnormal oxidation of the silicide layer and metal contamination of the apparatus for film deposition can be well prevented from occurring.

### Second Embodiment

While, in the foregoing the First Embodiment, silicide layers are formed, by means of salicide, not only on the dopant diffusion layers but also on the gate electrodes, in the present embodiment, an example wherein no silicide layers are formed on the gate electrodes is shown.

Firstly, after a gate insulating film 2 with a thickness of 2 nm to 20 nm or so is formed by the thermal oxidation method or the like on a semiconductor substrate 1 in which an element isolation region (not shown in the drawings) is set, a doped polycrystalline silicon layer with a thickness of 100 nm to 200 nm or so is formed over the entire surface by the CVD. Subsequently, after an insulating film of a silicon nitride film or such is formed into a thickness of 100 nm to 300 nm or so, this insulating film and the doped polycrystalline silicon film are patterned to form gate electrodes 3 each of which has, on the top face, a cap layer 31 made of an insulating film such as a silicon nitride film. Next, using the cap layer 31 and the gate electrodes 3 as a mask, an ion implantation is applied thereto, in the same way as the First Embodiment, and, thereby, dopant diffusion layers 4 are formed. The dopant diffusion layers 4 formed in this way are afterward subjected to a dopant activation treatment by means of a heat treatment conducted at 800° C. to 1000° C. or so, whereby source/drain regions of the MOSFET are formed.

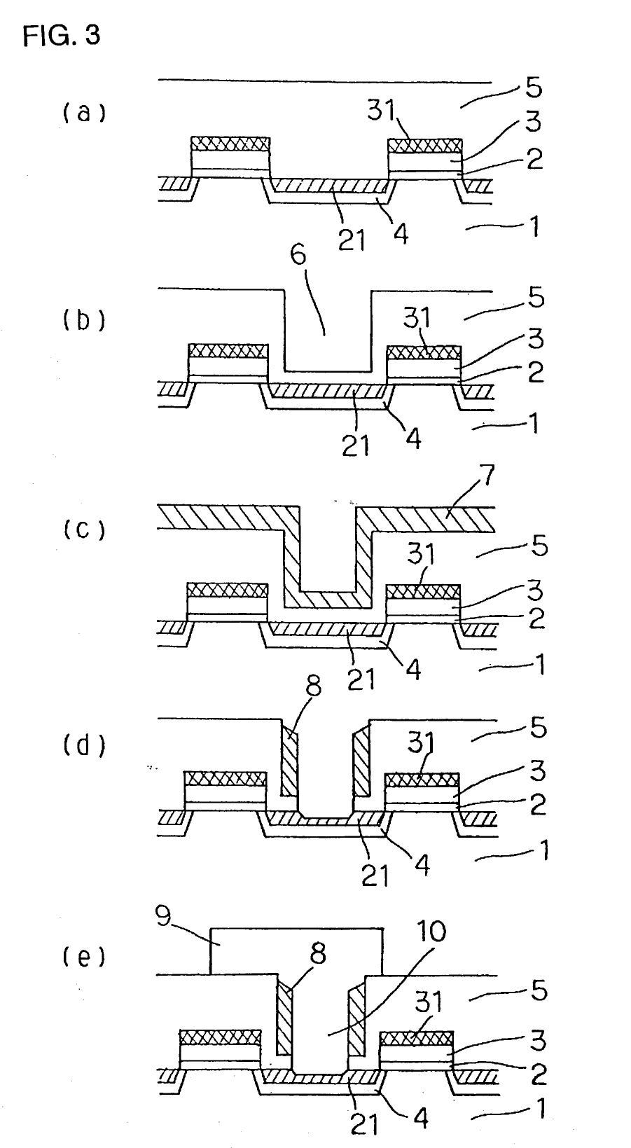

Next, in the same way as the First Embodiment, over the dopant diffusion layers, silicide layers 21 are formed. In the present embodiment, the silicide layers 21 are not formed on the gate electrodes but only on the dopant diffusion layers because the cap layers 31 are formed on the gate electrodes. After that, in the same way as the First Embodiment, an interlayer insulating film 5 is formed (FIG. 3(a)).

Next, as shown in FIG. 3 (b), an opening 6 is formed in the interlayer insulating film 5 by means of lithography and anisotropic etching. Thereat, etching is terminated before the silicide layers overlying the dopant diffusion layer 4 are exposed.

The etching end point can be determined in the same way as the First Embodiment. Moreover, since the cap layers 31 are set on the gate electrodes in the present embodiment, even if the margin between the contact and the gate electrode is small and the opening formed overlaps the position of the gate electrode because of the alignment shift or the like, the etching of the gate electrode can be prevented from taking place, with the cap layers 31 serving as etching stoppers.

Next, as shown in FIG. 3 (c), in the same way as the First Embodiment, an insulating film 7 for sidewall is formed from a silicon oxide film or such over the entire surface by the CVD.

Next, in the same way as the First Embodiment, an etch back is performed over the entire surface by anisotropic etching such as the RIE, and thereby sidewalls 8 are formed on the internal lateral faces of the opening and, at the same time, the silicide layer 21 overlying the dopant diffusion layer is exposed (FIG. 3(d)).

After that, as shown in FIG. 3(e), in the same way as the First Embodiment, an interconnection 9 as well as a contact 10 which connects this interconnection 9 with the dopant diffusion layer 4 are formed.

### Third Embodiment

In the present embodiment, there is presented a method, which is capable to terminate the etching at a prescribed depth in a more exact fashion than in the First and Second Embodiments.

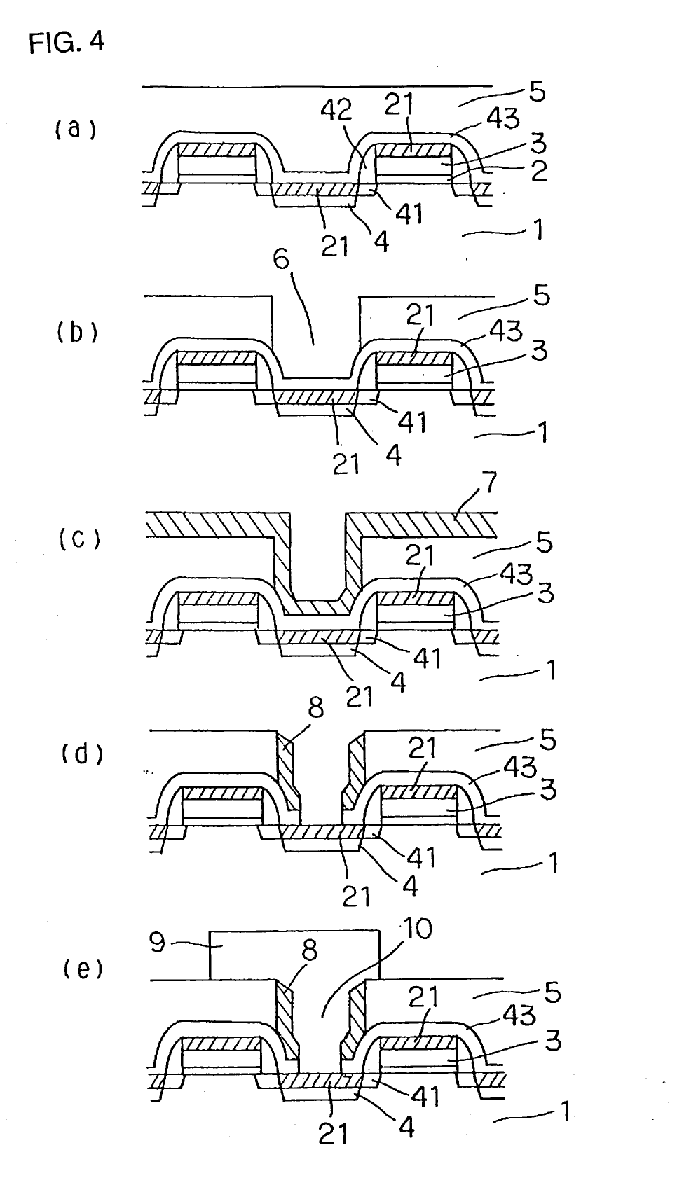

Firstly, after a gate insulating film 2 with a thickness of 2 nm to 20 nm or so is formed by the thermal oxidation method or the like on a semiconductor substrate 1 in which an element isolation region (not shown in the drawings) is set, a doped polycrystalline silicon layer with a thickness of 100 nm to 200 nm or so is formed over the entire surface by the CVD, and then, by patterning this layer, gate electrodes 3 are formed. Next, using the gate electrodes 3 as a mask, an ion implantation with a relatively low dose is performed under the condition that an accelerating energy is 5 keV to 50 keV and a dose is 1×10¹²/cm² to 5×10¹⁴/cm² or so, and, thereby, dopant diffusion layers 41 for the formation of LDD (Lightly Doped Drain) regions are formed. In this instance, boron (B) or BF₂ may be employed for the p-type dopants, and phosphorus (P) or arsenic (As), for the n-type dopants. Next, by the CVD method, a silicon oxide film 21 with a thickness of 50 nm to 200 nm is formed over the entire surface of the substrate so as to cover the gate electrodes 3. Subsequently, an etch back is performed over the entire surface by anisotropic etching, and thereby sidewalls 42 are formed from a silicon oxide film on the lateral faces of the gate electrodes. Next, using the sidewalls 42 and the gate electrodes 3 as a mask, an ion implantation is applied thereto, in the same way as the First Embodiment, and thereby dopant diffusion layers 4 for the formation of source/drain regions are formed. After that, in the same way as the First Embodiment, silicide layers 21 are formed on the dopant diffusion layers 4 as well as the gate electrodes 3. Next, over the entire surface, an etching stopper film 43 made of a silicon nitride film or such with a thickness of 10 nm to 100 nm or so is formed. This etching stopper film can be grown well, for example, by the plasma CVD, which is characterized by excellent step coverage, at or below 500° C., say, at 250° C. to 450° C. Further, as this etching stopper film is grown on the surface where silicide layers are exposed, the deposition of the film is to be carried out preferably at or below 600° C., and more preferably at or below 500° C., from the viewpoints of preventing abnormal oxidation of the silicide layers and metal contamination of the apparatus for film deposition. After that, in the same way as the First Embodiment, an interlayer insulating film 5 is formed (FIG. 4(a)).

Next, as shown in FIG. 4(b), in the interlayer insulating film 5, an opening 6 is formed to reach the etching stopper film 43 by means of lithography and anisotropic etching. In the present embodiment, the etching stopper film 43 is provided so that, even if the margin between the contact and the gate electrode is small and the opening formed overlaps the position of the gate electrode, the etching of the gate electrode or sidewall can be well prevented from taking place.

Next, as shown in FIG. 4 (c), in the same way as the First Embodiment, an insulating film 7 for sidewall is formed from a silicon oxide film or such over the entire surface by the CVD at or above 700° C. In the present embodiment, since the silicide layers 21 are covered with the etching stopper film 43 at the time of formation of the insulating film 7 for sidewall, even if the film deposition is carried out at a temperature of not less than 700° C., abnormal oxidation of the silicide layers and metal contamination of the apparatus for film deposition can be well prevented.

Next, in the same way as the First Embodiment, an etch back is performed over the entire surface by anisotropic etching such as the RIE, whereby he portion of the insulating film 7 lying in the bottom section of the opening is removed to make sidewalls 8 formed on the internal lateral faces of the opening and then the etching stopper film 43 lying in the bottom section of the opening is removed to expose the silicide layer 21 which is laid on top of the dopant diffusion layer (FIG. 4(d)).

After that, as shown in FIG. 4(e), in the same way as the First Embodiment, an interconnection 9 as well as a contact 10 which connects this interconnection 9 with the dopant diffusion layer 4 are formed.

In the present embodiment, the etching stopper film 43 made of a nitride film is formed directly over the semiconductor substrate. However, for example, in the case that sidewalls 42 are not provided on the lateral faces of the gate electrodes, a nitride film may be formed after an insulating film such as a silicon oxide film is formed, with the object of preventing the generation of an interface energy level that may arise if a nitride film is formed directly over the substrate. Because this insulating film formed to lie underneath the nitride film is, in consequence, formed directly over the substrate where silicide layers are exposed, the deposition of the insulating film is to be made preferably at or below 600° C., and more preferably at or below 500° C., from the viewpoints of preventing abnormal oxidation of the silicide layers and metal contamination of the apparatus for film deposition, as describe above.

What is claimed is:

1. A method of manufacturing a semiconductor device; which comprises the steps of:
forming an interlayer insulating film on a semiconductor substrate having a gate electrode, a dopant diffusion layer and a silicide layer which is set on said dopant diffusion layer;
forming an opening in said interlayer insulating film which is laid on said dopant diffusion layer in such a way that said silicide layer may not be exposed;
forming, in a region inclusive of internal lateral faces of said opening, an insulating film for sidewall at or above 700° C. by the CVD;
performing an etch back and thereby forming, on the internal lateral face of said opening, a sidewall made of said insulating film for sidewall and, at the same time, removing said interlayer insulating film lying under said opening, whereby a contact hole to expose said silicide layer is formed; and
filling up said contact hole with a conductive material.

2. A method of manufacturing a semiconductor device according to claim 1, wherein said interlayer insulating film is grown at or below 600° C.

3. A method of manufacturing a semiconductor device according to claim 1, wherein said insulating film for sidewall is a silicon oxide film.

4. A method of manufacturing a semiconductor device according to claim 1 wherein said CVD is the low-pressure CVD.

5. A method of manufacturing a semiconductor device according to claim 1, wherein said gate electrode has a silicide layer on top, and said opening is set in such a way that its bottom face is placed in position higher than the top face of the silicide layer overlying said gate electrode.

6. A method of manufacturing a semiconductor device; which comprises the steps of:
forming a first insulating film on a semiconductor substrate having a gate electrode, a dopant diffusion layer and a silicide layer which is set on said dopant diffusion layer, and subsequently forming an interlayer insulating film thereon;
forming, in said interlayer insulating film which is laid on said dopant diffusion layer, an opening to reach said first insulating film, using said first insulating film as an etching stopper;
forming, in a region inclusive of internal lateral faces of said opening, a second insulating film at or above 700° C. by the CVD;
performing an etch back and thereby removing said second insulating film lying under said opening to form, on the internal lateral face of said opening, a sidewall made of said second insulating film, and, subsequently, removing said first insulating film lying under said opening, whereby a contact hole to expose said silicide layer is formed; and
filling up said contact hole with a conductive material.

7. A method of manufacturing a semiconductor device according to claim 6, wherein said first insulating film is grown at or below 600° C.

8. A method of manufacturing a semiconductor device according to claim 6, wherein said second insulating film is a silicon oxide film.

9. A method of manufacturing a semiconductor device according to claim 6, wherein said CVD is the low-pressure CVD.

10. A method of manufacturing a semiconductor device according to claim 6, wherein said first insulating film is a silicon nitride film.
